(19) United States
(12) Patent Application Publication
(10) Pub. No.: US 2009/0231819 A1
(43) Pub. Date: Sep. 17, 2009

(54) MULTILAYER SUBSTRATE

(75) Inventors: Yoshiaki SATAKE, Kanagawa-ken (JP); Taihei Nakada, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/331,769

(22) Filed: Dec. 10, 2008

(30) Foreign Application Priority Data
Mar. 14, 2008 (JP) 2008-066245

(51) Int. Cl. H05K 1/18

(52) U.S. Cl. 361/762

(57) ABSTRACT

A multilayer substrate has a 1st strip line, a 2nd strip line and the 3rd strip line, and those characteristic impedances are different each other. The third strip line has a strip conductor of which length is equivalent to ¼ wavelength of an operating frequency. A strip conductor of the third strip line is the same conductor as a strip conductor of the first strip line, and is a different conductor layer from a strip conductor of the second strip line. Ground conductors of the 3rd strip line are formed of the same conductor layer as one of a ground conductor of the 1st strip line, and the same conductor layer as one of a ground conductor of the 2nd strip line. The strip conductor of the second strip line and the strip conductor of the third strip line are connected through via hole arranged in the multilayer substrate.

### CROSS REFERENCE TO RELATED APPLICATION

This application is based upon and claims the benefit of priority from the prior Japanese Patent Application No. 2008-66245, filed on Mar. 14, 2008, the entire contents of which are incorporated herein by reference.

### FIELD OF THE INVENTION

The present invention relates to a multilayer substrate which transmits a high frequency signal, for example.

### DESCRIPTION OF THE BACKGROUND

In prior art, layer conversion of a strip conductor and distance conversion between ground conductors in a strip line in a multilayer substrate were designed so that characteristic impedances of lines before and after conversion might become the same.

However, even if the characteristic impedances of the lines before conversion and after conversion are designed to coincide, it was difficult to make the characteristic impedance of the layer conversion part completely coincide with a desired value because of design restrictions at the time of manufacturing conductor for interlayer connections, such as a via hole, of the layer conversion part and near the layer conversion part. Because of mismatch of this characteristic impedance, a standing wave occurred in the strip line and the electromagnetic wave propagation characteristic of the strip line was bad.

As a method for making characteristic impedances of the lines coincide before and after layer conversion, there is a method in which the pattern widths of the lines are changed before and after layer conversion in consideration of the characteristic impedances of the lines before and after conversion. However, in a high frequency circuit or a circuit of a small area, various problems on a design of the pattern width arise. For example, if pattern width is too small, a problem on which degradation of reliability of performance by a manufacturing process occurs, and a problem on which propagation loss of the line becomes large will arise. In dense patterning, if the pattern width is too large, the problem on which the line comes too close with other lines and a signal quality deteriorates will arise.

By forming a cutout part in a ground conductor of the strip line and providing a through hole between the strip lines in a portion which the strip lines are connected by the through hole, a connection structure of the strip line which has good reflective characteristic in high frequency is proposed (for example, refer to JP2003-168903A). However, in a layer conversion of JP2003-168903A, a strip conductor after the layer conversion is located in place more distant from the ground conductor before the layer conversion, viewing from a strip conductor before the layer conversion. From this, this technique is inapplicable to a conversion which each same ground conductor layer is shared before the layer conversion and after the layer conversion. In a layer conversion part shown by JP2003-168903A, since it is necessary to provide the through hole for connection in a ground conductor pattern, an installed position must be designed and it may become a burden in the case of design.

As mentioned above, as for a conventional multilayer substrate, electromagnetic wave propagation characteristic of the strip line gets worse easily on the occasion of layer conversion and conversion of distance between ground conductors. When it is tried to avoid aggravation of this electromagnetic wave propagation characteristic, it is necessary to take many design matters into consideration.

### SUMMARY OF THE INVENTION

The present invention was made in order to cope with the above-mentioned situation. An object of the invention is to provide a multilayer substrate which can reduce a burden at the time of a substrate design, and can change a layer of a strip line and a distance between ground conductors without deterioration of the electromagnetic wave propagation characteristic of the strip line.

To achieve the above purpose, a multilayer substrate according to the present invention has a plurality of dielectric layers and a plurality of conductor layers laminated via the dielectric layers, respectively, and has a first region, a second region and a third region. The first region has a first strip line including a first strip conductor formed in a first intermediate conductor layer and a first and a second ground conductors formed of conductor layers provided both sides of the first intermediate conductor layer. The second region has a second strip line including a second strip conductor formed in a second intermediate conductor layer which differs from the first intermediate conductor layer, and third ground conductor formed of the same conductor layer as the first ground conductor and the fourth ground conductor formed of a different conductor layer from the second ground conductor. The third region is located between the first and second regions. The third region has a strip line for connection including a strip conductor for connection formed in the first intermediate conductor layer by extending the first strip conductor by ¼ wavelength of a transmission signal with the same pattern width, and a fifth ground conductor formed of the same conductor layer as the first ground conductor and a sixth ground conductor formed of the same conductor layer as the fourth ground conductor. Furthermore, a connection portion for connecting an end portion of the strip conductor for connection of the third region and an end portion of the second strip conductor of the second region is provided.

In the multilayer substrate, the first region in which the first strip line was formed, and the second region in which the second strip line having second strip conductor located in a different layer from the first strip conductor is formed, are connected via the third region in which the strip line for connection is formed.

As for the strip line for connection, the first strip conductor is extended by a length equivalent to ¼ wavelength of a transmission signal with the same pattern width. At this time, the end of the strip conductor for connection and the end of the second strip conductor are electrically connected by a connection portion for connecting. Thus, as for the multilayer substrate, by connecting the first and second regions via the third region, a difference in characteristic impedances will be matched in the strip conductor for connection of the third region.

### BRIEF DESCRIPTION OF THE DRAWINGS

FIG. 1 is a perspective view of a multilayer substrate according to first embodiment according to the present invention.

FIG. 2 is a cross-sectional view taken along an A-A line in FIG. 1.

FIG. 3 is a perspective view of a multilayer substrate according to second embodiment according to the present invention.

FIG. 4 is a cross-sectional view taken along a B-B line in FIG. 3.

### DETAILED DESCRIPTION OF THE INVENTION

Hereinafter, embodiments according to the present invention are explained in detail with reference to the drawings.

### Embodiment 1

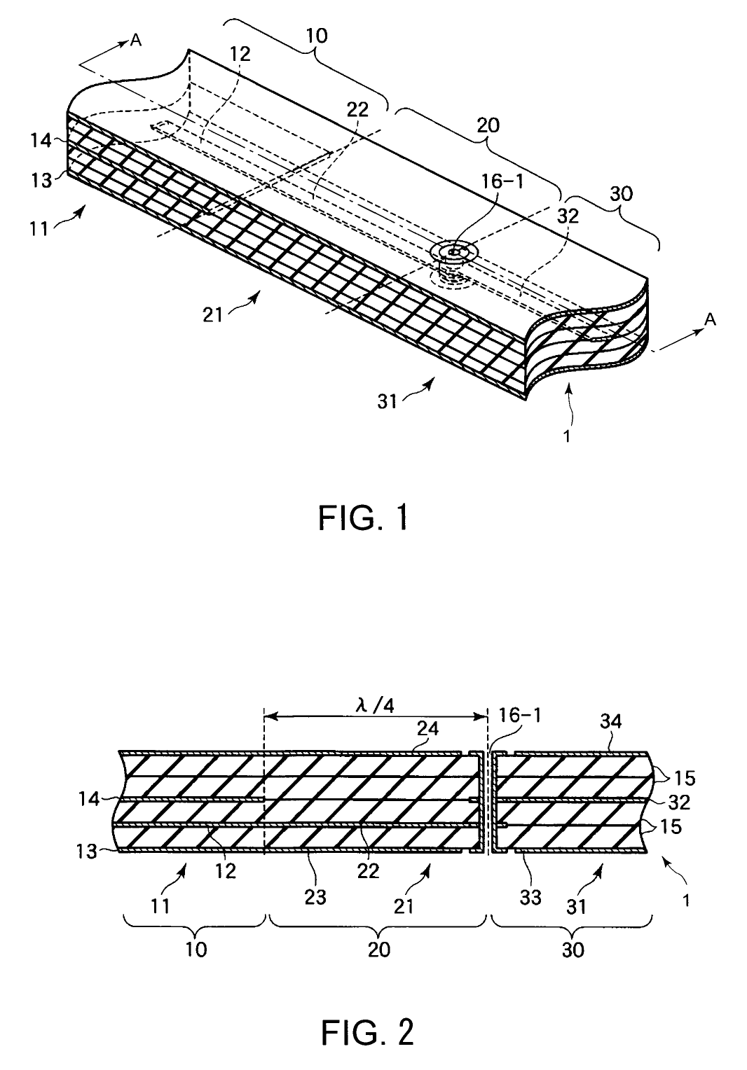

FIG. 1 is a perspective view of a multilayer substrate according to the first embodiment of the present invention. FIG. 2 is a cross-sectional view taken along an A-A line in FIG. 1. Multilayer substrate 1 shown in FIG. 1 has a five-layer substrate structure which has five conductor layers laminated via four dielectric layers 15, respectively. In FIG. 1, since one conductor layer between upper dielectric layers 15 was removed, only four conductor layers are shown. Multilayer substrate 1 possesses region 10, region 20, and region 30 located between region 10 and region 20, and strip line is formed in each region.

Strip line 11 is formed in region 10. Strip line 11 has strip conductor 12 formed of a first intermediate conductor layer, and has ground conductors 13 and 14 formed of conductor layers provided both sides of strip conductor 12. A distance between strip conductor 12 and ground conductor 13 and a distance between strip conductor 12 and ground conductor 14 are equal.

Strip line 31 is formed in region 30. Strip line 31 has strip conductor 32 formed of a second intermediate conductor layer different from the first intermediate conductor layer, and has ground conductors 33 and 34 formed of conductor layers provided both sides of strip conductor 32. Strip conductor 32 is in the same pattern width as strip conductor 12, and is located in a layer which is different from strip conductor 12. Ground conductor 33 is the same layer as ground conductor 13, and ground conductor 34 is a different layer from ground conductor 14. Strip conductor 32 is formed in the same conductor layer as ground conductor 14. A distance between strip conductor 32 and ground conductor 33 and a distance between strip conductor 32 and ground conductor 34 are equal.

Strip line 21 is formed in region 20. Strip line 21 has strip conductor 22 formed of the first intermediate conductor layer and has ground conductors 23 and 24 formed of conductor layers provided both sides of strip conductor 22. Strip conductor 22 is the same pattern width as strip conductor 12, and is formed by extending strip conductor 12 by a length equivalent to ¼ wavelength of a transmission signal. Ground conductor 23 is the same layer as ground conductor 13, and ground conductor 24 is the same layer as ground conductor 34. At this time, a distance between strip conductor 22 and ground conductor 23 is smaller than a distance between strip conductor 22 and ground conductor 24.

Via hole, for example through hole 16-1, is arranged between region 20 and region 30, and it is provided in parallel to a lamination up-and-down direction of multilayer substrate 1. Through hole 16-1 electrically connects an end portion of strip conductor 22 and an end portion of strip conductor 32.

Transmission of a signal in multilayer substrate 1 of above-mentioned composition is explained in detail.

Multilayer substrate 1 transmits a transmission signal to strip conductor 32 connected by through hole 16-1 via strip conductor 22 from strip conductor 12. At this time, a characteristic impedance of strip line 11 and a characteristic impedance of strip line 31 differ mutually. Strip line 21 almost fulfills conditions to match these characteristic impedances. The conditions to match different characteristic impedances are that a characteristic impedance of strip line 21 is almost square root of a product of the characteristic impedance of strip line 11 and the characteristic impedance of strip line 31, and a length of strip line 21 is (2n−1)×¼ (n is an integer) of a wavelength of the transmission signal. In this embodiment, the above-mentioned conditions is fulfilled by extending strip conductor 12 by a length equivalent to ¼ wavelength of the transmission signal to form strip conductor 22 by an extended part, and letting ground conductor 23 and ground conductor 13 be the same layer, and letting ground conductor 24 and ground conductor 34 be the same layer.

As mentioned above, in multilayer substrate 1 according to the first embodiment, strip line 11 of region 10 is electrically connected with strip line 31 of region 30 via strip line 21 of region 20. At this time, strip line 21 fulfills conditions to match the characteristic impedance of strip line 11 with the characteristic impedance of strip line 31.

By this, when multilayer substrate 1 transmits a transmission signal of which quarter-wavelength corresponds to the length of strip line 21, a difference between a characteristic impedance of strip line 11 and a characteristic impedance of strip line 31 will be matched by strip line 21. That is, a reflection of electromagnetic wave in line propagation in an operating frequency will be reduced.

From the above-mentioned conditions, with a high frequency signal of frequency other than the operating frequency, since matching of characteristic impedances does not take place in many cases, reflection of electromagnetic waves has an increasing tendency. That is, it becomes possible to suppress electromagnetic wave propagation of frequency other than the operating frequency. Thereby, an effect of a frequency filter can be added in the case of the layer conversion in the strip line.

Since generating of reflection of electromagnetic waves can be suppressed by forming strip line 21 between strip line 11 and strip line 31, it becomes unnecessary to perform strict adjustment of characteristic impedance in a layer conversion part. That is, it is restricted to neither design conditions of a conductor for a interlayer connection, such as a via hole, nor design conditions of its neighborhood, and it becomes possible to design the layer conversion of the strip line freely more.

Furthermore, it becomes unnecessary to make the characteristic impedance of strip line 11 and the characteristic impedance of strip line 31 coincide by forming strip line 21 between strip line 11 and strip line 31. Thereby, pattern width of all the strip conductors can be made the same. That is, multilayer substrate 1 according to the embodiment can solve a problem of the design matter about pattern width.

In a line on which structure of a ground conductor in the strip line changes, the necessity of newly providing a design factor for realizing matching over this structural change decrease. For this reason, in the state with few elements which may generate mismatching, with a simpler structure, a good electromagnetic wave propagation characteristic which does not generate reflection of electromagnetic waves can be obtained.

Therefore, the multilayer substrate according to the first embodiment can reduce a burden at the time of the substrate design, and can change the layer of the strip line and distance between ground conductors without deterioration of the electromagnetic wave propagation characteristic of the strip line.

### Embodiment 2

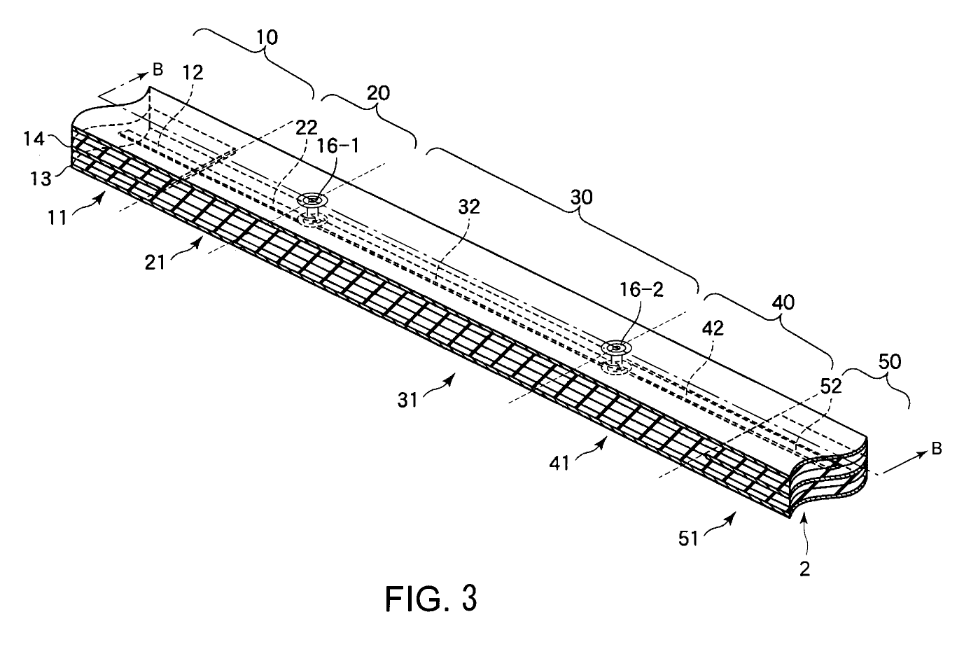

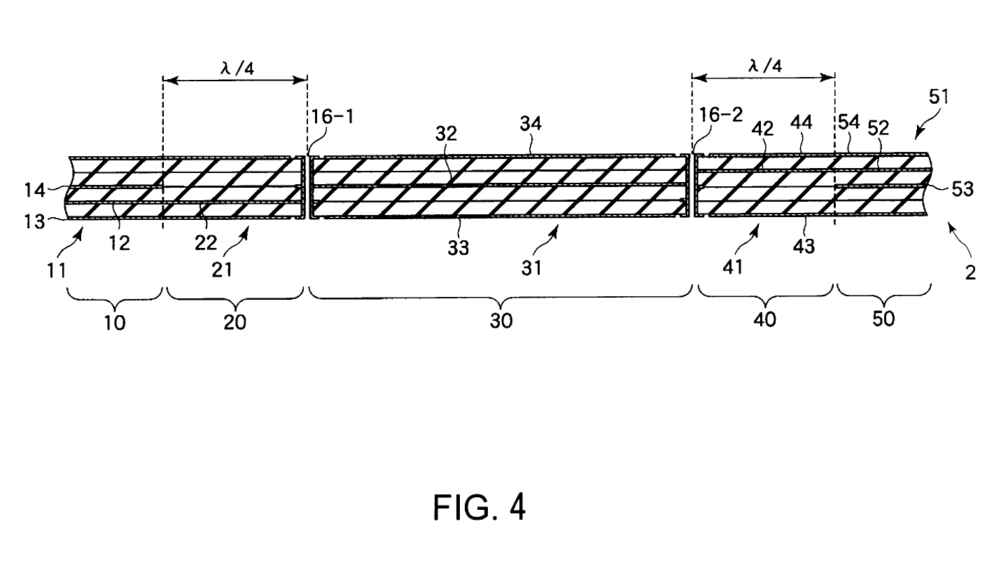

FIG. 3 shows a perspective view of a multilayer substrate according to the embodiment 2 of the present invention. FIG. 4 shows a cross-sectional view taken along B-B line in FIG. 3. Multilayer substrate 2, shown in FIG. 3, has a five-layer substrate structure which has five conductor layers laminated via four dielectric layers 15, respectively. In addition to the multilayer substrate of FIG. 1, multilayer substrate 2 has regions 40 and 50, and there are two layer conversions. A length of strip line 31 in region 30 is set up arbitrarily.

Strip line 51 is formed in region 50. Strip line 51 has strip conductor 52 formed of a third conductor layer and ground conductors 53 and 54 formed of conductor layers provided both sides of strip conductor 52. Here, strip conductor 52 is the same pattern width as strip conductor 32, and is located in a layer which is different from strip conductor 32. Ground conductor 54 is the same layer as ground conductor 34, and ground conductor 53 is a different layer from ground conductor 33. Ground conductor 53 is formed in the same conductor layer as strip conductor 32. A distance between strip conductor 52 and ground conductor 53 and a distance between strip conductor 52 and ground conductor 54 are equal.

Strip line 41 is formed in region 40. Strip line 41 has strip conductor 42 formed of a third conductor layer and ground conductors 43 and 44 formed of conductor layers provided both sides of strip conductor 42. Here, strip conductor 42 is the same pattern width as strip conductor 52, and is formed by extending strip conductor 52 by a length equivalent to ¼ wavelength of a transmission signal. Ground conductor 43 is the same layer as ground conductor 33, and ground conductor 44 is the same layer as ground conductor 54. At this time, a distance between strip conductor 42 and ground conductor 44 is smaller than a distance between strip conductor 42 and ground conductor 43.

In addition, the layer of strip conductor 12 of strip line 11 into which the transmission signal is inputted, and the layer of strip conductor 52 of strip line 51 from which the transmission signal is outputted are different, respectively.

Through hole 16-2 is arranged between region 30 and region 40, and is provided in parallel to a lamination up-and-down direction of multilayer substrate 2. Through hole 16-1 electrically connects an end portion of strip conductor 32 and an end portion of strip conductor 42.

As mentioned above, in the multilayer substrate according to the embodiment 2, strip line 11 of region 10 is electrically connected with strip line 31 of region 30 via strip line 21 of region 20, and strip line 31 of region 30 is electrically connected with strip line 51 of region 50 via strip line 41 of region 40. At this time, strip line 21 fulfills the conditions to match the characteristic impedance of strip line 11 and the characteristic impedance of strip line 31, and strip line 41 fulfills conditions to match a characteristic impedance of strip line 31 and a characteristic impedance of strip line 51.

Thereby, when transmitting a high frequency signal of which quarter-wavelength corresponds to each length of strip lines 21 and 41, a difference between the characteristic impedance of strip line 11 and the characteristic impedance of strip line 31 is matched by strip line 21. Furthermore, a difference between the characteristic impedance of strip line 31 and the characteristic impedance of strip line 51 is matched by strip line 41. That is, a reflection of electromagnetic waves in line propagation in an operating frequency will be reduced.

In a high frequency signal of frequency other than the operating frequency, since matching of the characteristic impedances does not take place in many cases, electromagnetic wave propagation of the frequency other than the operating frequency can be suppressed. Thereby, an effect of a frequency filter can be added in the case of layer conversion in the strip line.

Since multilayer substrate 2 performs the layer conversion twice, a high frequency signal passes these frequency filters twice in this embodiment. Thereby, multilayer substrate 2 can make more remarkable the effect which suppresses electromagnetic wave propagation of the frequency other than the operating frequency.

Furthermore, by forming strip line 21 between strip line 11 and strip line 31, and by forming strip line 41 between strip line 31 and strip line 51, generating of reflection of electromagnetic waves can be suppressed. Thereby, it becomes unnecessary to perform strict adjustment of characteristic impedance in a layer conversion part. That is, it is restricted to neither design conditions of a conductor for a interlayer connection, such as a via hole, nor design conditions of its neighborhood, and it becomes possible to design the layer conversion of the strip line freely more.

By forming strip line 21 between strip line 11 and strip line 31, it becomes unnecessary to make the characteristic impedance of strip line 11 and the characteristic impedance of strip line 31 coincide. And forming strip line 41 between strip line 31 and strip line 51, it becomes unnecessary to make the characteristic impedance of strip line 31 and the characteristic impedance of strip line 51 coincide. Thereby, it becomes possible to make the pattern width of all the strip conductors the same. That is, multilayer substrate 2 according to this embodiment can solve the problem of the design matter about the pattern width.

Furthermore, in a line in which a structure of the ground conductors in the strip line changes, the necessity of newly providing a design factor for realizing matching over this structural change decreases. For this reason, in the state with few elements which may generate mismatching, with a simpler structure, good electromagnetic wave propagation characteristic which does not generate reflection of electromagnetic waves can be obtained.

Therefore, multilayer substrate 2 according to the embodiment 2 can reduce a burden at the time of the substrate design, and can change the layer of the strip line, and change the distance between ground conductors without aggravation of the electromagnetic wave propagation characteristic of the strip line.

(Modification)

The multilayer substrate according to the present invention is not necessarily limited to the embodiments mentioned above. For example, in each above-mentioned embodiment, an example of the multilayer substrate of five-layer substrate structure is explained, but the present invention is not necessarily restricted to the multilayer substrate of five-layer substrate structure.

Although each above-mentioned embodiment explained the example which performs the layer conversion once or twice, the number of times of conversion does not necessarily have restrictions. In addition, increasing the number of times of this layer conversion makes more remarkable the effect which the electromagnetic wave of only the operating frequency propagates.

Other embodiments or modifications of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A multilayer substrate having a plurality of dielectric layers and a plurality of conductor layers laminated via said dielectric layers, the multilayer substrate, comprising:
a first region having a first strip line, said first strip line including a first strip conductor formed in a first intermediate conductor layer within said plurality of conductor layers and a first and a second ground conductors formed of said conductor layers provided both sides of the first intermediate conductor;
a second region having a second strip line, said second strip line including a second strip conductor formed in a second intermediate conductor layer different from said first intermediate conductor layer within said plurality of conductor layers, a third ground conductor formed of the same conductor layer as said first ground conductor and a fourth ground conductor formed of a different conductor layer from said second ground conductor, said third ground conductor and said fourth ground conductor being provided both sides of said second intermediate conductor layer;
a third region located between said first and second region, said third region having a strip line for connection including a strip conductor for connection formed in said first intermediate conductor layer by extending said first strip conductor by a length of (2n−1)×¼ (n is an integer) of a wavelength of a transmission signal with the same pattern width, a fifth ground conductor formed of the same conductor layer as said first ground conductor, and a sixth ground conductor formed of the same conductor layer as said fourth ground conductor; and
a connection portion for connecting an end portion of said strip conductor for connection of said third region and an end portion of said second strip conductor of said second region.

2. The multilayer substrate according to claim 1, wherein a distance between said first intermediate conductor layer and said conductor layer used as said first ground conductor and a distance between said first intermediate conductor layer and the conductor layer used as said second ground conductor are equal, and a distance between said second intermediate conductor layer and said conductor layer used as said third ground conductor and a distance between said second intermediate conductor layer and said conductor layer used as said fourth ground conductor are equal.

3. The multilayer substrate according to claim 1, wherein said second intermediate conductor layer is same said conductor layer as said conductor layer used as said second ground conductor.

4. The multilayer substrate according to claim 1, wherein said connection portion for connecting is a via hole.

5. The multilayer substrate according to claim 1, wherein pattern width of said second strip conductor is the same as pattern widths of said first strip conductor and said strip conductor for connection.
